(19) United States
(12) Patent Application Publication
(10) Pub. No.: US 2026/0304922 A1
(43) Pub. Date: Oct. 1, 2026

(54) SEMICONDUCTOR DEVICE AND METHOD FOR FORMING THE SAME

(71) Applicant: Vanguard International Semiconductor Corporation, Hsinchu (TW)

(72) Inventors: Wen-Shan LEE, Hsinchu City (TW); Chen-Dong TZOU, Taipei City (TW); Chung-Yeh LEE, Xinpu Township (TW); Fu-Hsin CHEN, Zhudong Township (TW)

(73) Assignee: Vanguard International Semiconductor Corporation, Hsinchu (TW)

(21) Appl. No.: 19/092,422

(22) Filed: Mar. 27, 2025

(51) Int. Cl. H10D 84/83; H10D 12/00; H10D 62/832; H10D 84/01

(52) U.S. Cl. CPC H10D 84/8311; H10D 84/0135; H10D 84/0149; H10D 84/8312; H10D 84/83138; H10D 84/837; H10D 12/481; H10D 62/8325

(57) ABSTRACT

A semiconductor device and a method for forming the same are provided. The semiconductor device includes a silicon carbide substrate, first and second epitaxial layers, a gate structure and a contact feature. The silicon carbide substrate of a first conductivity type has a first active region. The first epitaxial layer of a second conductivity type is disposed on the silicon carbide substrate. The second epitaxial layer of the first conductivity type is disposed on the first epitaxial layer. The gate structure is disposed in the silicon carbide substrate in the first active region and passes through the first epitaxial layer. The contact feature extends from the top surface of the second epitaxial layer in the first active region, through the first epitaxial layer and into the silicon carbide substrate. The first contact feature is electrically connected to the silicon carbide substrate and the first epitaxial layer.

### BACKGROUND OF THE INVENTION

### Field of the Invention

The present disclosure relates to a semiconductor device and a method for forming the same, and, in particular, it relates to a trench insulated gate bipolar transistor and a method for forming the same.

### Description of the Related Art

The semiconductor industry continues to improve the integration density of different electronic components, thereby allowing more components to be integrated into a given area by continuing to reduce minimum component sizes. For example, trench gate metal-oxide-semiconductor field effect transistors (MOSFETs), which are widely used in power switches, use a vertical structure design to increase functional density by reducing cell pitch. A trench gate MOSFET uses the back side of the chip as a drain electrode, and forms the source electrodes and the gate electrodes of multiple transistors on the front side of the chip. Therefore, the driving current flows from the horizontal direction to the vertical direction. A trench gate MOSFET also enables the semiconductor device to achieve a high reverse withstand voltage and low on-resistance.

However, as the functional density requirements on semiconductor devices continue to increase, the complexity of integrated components in the semiconductor devices, as well as the complexity of the methods of forming semiconductor devices, also increases. In addition, those electronic characteristics that have performance trade-offs need careful con-sideration. Although existing semiconductor devices are generally suitable and sufficient for their intended purposes, they have not been entirely satisfactory in all respects.

### BRIEF SUMMARY OF THE INVENTION

An embodiment of the disclosure provides a semiconductor device. The semi-conductor device includes a silicon carbide substrate, a first epitaxial layer, a second epitaxial layer, a first gate structure, and a first contact feature. The silicon carbide substrate has a first active region and a second active region. The silicon carbide substrate has a first conductivity type. The first epitaxial layer is disposed on a top surface of the silicon carbide substrate. The first epitaxial layer has a second conductivity type. The second epitaxial layer is disposed on a top surface of the first epitaxial layer. The second epitaxial layer has the first conductivity type. The first gate structure is disposed in the first active region of the silicon carbide substrate. The first gate structure extends from the silicon carbide substrate through the first epitaxial layer in a first direction. The first contact feature extends from a top surface of the second epitaxial layer of the first active region, through the first epitaxial layer and to the silicon carbide substrate in the first direction. The first contact feature and the first gate structure are separated from each other in a second direction, and the first contact feature is electrically connected to the silicon carbide substrate and the first epitaxial layer.

Another embodiment of the disclosure provides a method for forming a semi-conductor device. The method for forming a semiconductor device includes providing a silicon carbide substrate. The silicon carbide substrate has a first active region and a first conductivity type. The method also includes growing a first epitaxial layer on a top surface of the silicon carbide substrate. The first epitaxial layer has a second conductivity type. The method also includes growing a second epitaxial layer on a top surface of the first epitaxial layer. The second epitaxial layer has the first conductivity type. The method also includes forming a first trench in the second epitaxial layer, the first epitaxial layer and a portion of the silicon carbide substrate in the first active region in a first direction. The method also includes forming a first gate electrode in the first trench. The method also includes forming a second trench in the second epitaxial layer and a portion of the first epitaxial layer in the first active region in the first direction. The first trench and the second trench are spaced apart from each other in a second direction The method also includes forming a first contact feature in the second trench. The first contact feature extends through the first epitaxial layer and into the silicon carbide substrate in the first direction.

### BRIEF DESCRIPTION OF THE DRAWINGS

The present invention can be more fully understood by reading the subsequent detailed description and examples with references made to the accompanying drawings, wherein:

FIG. 1 is a schematic cross-sectional view of a semiconductor device in accordance with some embodiments of the disclosure; and

FIGS. 2, 3, 4, 5, 6, 7, 8, 9, 10, 11, 12, 13, 14, 15, 16, 17, 18, 19, 20, 21, 22, 23, and 24 are cross-sectional views of intermediate stages of forming the semiconductor device of FIG. 1 in accordance with some embodiments of the disclosure.

### DETAILED DESCRIPTION OF THE INVENTION

The embodiments of the present disclosure are fully described herein with reference to the accompanying drawings. It should be noted, however, that the present disclosure is not limited to the following exemplary embodiments, and may be implemented in various forms. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the disclosure.

The following disclosure provides various embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

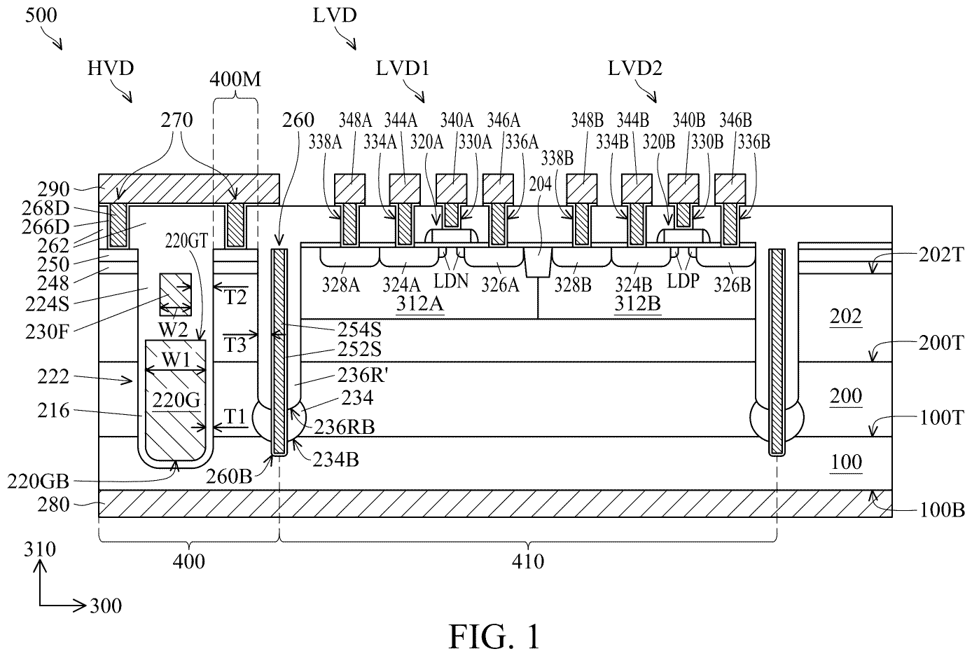

FIG. 1 is a schematic cross-sectional view of a semiconductor device 500 in accordance with some embodiments of the disclosure. In some embodiments, the semiconductor device 500 may at least include a high voltage vertical component such as a trench insulated gate bipolar transistor (trench IGBT). In some embodiments, the semiconductor device 500 may include a silicon carbide substrate 100, a first epitaxial layer 200, a second epitaxial layer 202, and a first type semiconductor component HVD. The first type semi-conductor component HVD may include a gate structure 222 and a first contact feature 260.

As shown in FIG. 1, the silicon carbide substrate 100 has a top surface 100T and a bottom surface 100B. Furthermore, the silicon carbide substrate 100 may have at least a first active region 400. In some embodiments, the first active region 400 may be an active region provided for high voltage vertical components such as trench insulated gate bipolar transistor (IGBT) arrays formed therein. In the following embodiments, one first type semi-conductor component HVD (e.g., one trench insulated gate bipolar transistor) unit is used as an example for the structural description in a high voltage vertical device active region. However, any number of first-type semiconductor component HVD units may be disposed in the high-voltage vertical device active region and is not limited to the embodiments described herein.

In some embodiments, the conductivity type of the silicon carbide substrate 100 may be P-type or N-type according to design requirements of the products. In this embodiment, the silicon carbide substrate 100 may be doped with dopants to have a first conductivity type, such as N-type. When the first conductivity type is N-type, the dopant with the first conductivity type may include phosphorus (P), arsenic (As), antimony (Sb) or other suitable dopants. Furthermore, the doping concentration of the silicon carbide substrate 100 is about 10¹⁹-10²¹ atoms/cm³, and can be regarded as an N-type heavily doped (N+) silicon carbide substrate 100. In the applications of trench insulated gate bipolar transistors, the silicon carbide substrate 100 having the first conductivity type may serve as the emitter region (or the source region) of the resulting first type semiconductor component HVD.

The first epitaxial layer 200 is disposed on the top surface 100T of the silicon carbide substrate 100. In some embodiments, the first epitaxial layer 200 may be doped with dopants to have a second conductivity type, wherein the second conductivity type is the opposite of the first conductivity type. Furthermore, the dopant with the second conductivity type may include aluminum (Al), boron (B), boron difluoride (BF₂) or other suitable dopants. For example, when the silicon carbide substrate 100 is an N-type silicon carbide substrate 100, the first epitaxial layer 200 is a P-type epitaxial layer 200. Furthermore, the doping concentration of the first epitaxial layer 200 is about 10¹⁷-10¹⁸ atoms/cm³. In the applications of trench insulated gate bipolar transistors, the epitaxial layer 200 having the first conductivity type may serve as a channel region of the resulting first type semiconductor component HVD. In some embodiments, the first epitaxial layer 200 includes silicon carbide.

The second epitaxial layer 202 is disposed on the top surface 200T of the first epitaxial layer 200. In some embodiments, the second epitaxial layer 202 may be doped with dopants to have the first conductivity type. For example, when the silicon carbide substrate 100 is an N-type silicon carbide substrate 100, the second epitaxial layer 202 is an N-type epitaxial layer 202. Furthermore, the doping concentration of the second epitaxial layer 202 (e.g., about 10¹⁵-10¹⁶ atoms/cm³) is lower than the doping concentration of the silicon carbide substrate 100 (e.g., about 10¹⁹-10²¹ atoms/cm³). For example, when the silicon carbide substrate 100 is an N-type heavily doped (N+) silicon carbide substrate 100, the second epitaxial layer 202 is an N-type lightly doped (N−) epitaxial layer 202. In the applications of trench insulated gate bipolar transistors, the second epitaxial layer 202 having the first conductivity type may serve as a drift region of the resulting first type semiconductor component HVD. In some embodiments, the second epitaxial layer 202 includes silicon carbide.

The gate structure 222 of the first type semiconductor component HVD is disposed in a portion of the silicon carbide substrate 100, the first epitaxial layer 200 and a portion of the second epitaxial layer 202 in the first active region 400. As shown in FIG. 1, the gate structure 222 is located close to the bottom surface 100B of the silicon carbide substrate 100 and away from the top surface of the second epitaxial layer 202. The gate structure 222 extends from the silicon carbide substrate 100, through the first epitaxial layer 200 and to a portion of the second epitaxial layer 202 in a direction 310 (a direction substantially perpendicular to the top surface 100T of the silicon carbide substrate 100 and the direction 300, which may also serve as a longitudinal direction). In some embodiments, the gate structure 222 of the first type semiconductor component HVD includes a gate dielectric layer 216 and a gate electrode 220G.

The gate dielectric layer 216 may extend from a position close to the top surface 202T of the second epitaxial layer 202 in the first active region 400, through the first epitaxial layer 200, and into a portion of the silicon carbide substrate 100 in the direction 310. In some embodiments, the gate dielectric layer 216 may be silicon oxide, another suitable dielectric material, or a combination thereof. In some embodiments, the gate dielectric layer 216 may be formed by a conformably deposition process, an oxidation process, or another suitable process. In some embodiments, the oxidation process may be thermal oxidation or another suitable process. In some embodiments, the deposition process may be a physical vapor deposition (PVD) process, a chemical vapor deposition (CVD) process, a plasma-enhanced chemical vapor deposition (PECVD), another suitable process, or a combination thereof.

The gate electrode 220G is located on the gate dielectric layer 216. As shown in FIG. 1, the gate electrode 220G extends from the silicon carbide substrate 100, through the first epitaxial layer 200 and to a portion of the second epitaxial layer 202 in the direction 310. In the direction 310, the top surface 220GT of the gate electrode 220G may be located above the top surface 200T of the first epitaxial layer 200 (i.e., the top surface 220GT of the gate electrode 220G is closer to the top surface 202T of the second epitaxial layer 202 than the top surface 200T of the first epitaxial layer 200). Furthermore, the gate dielectric layer 216 covers the bottom surface and opposite sidewalls of the gate electrode 220G. In some embodiments, the gate electrode 220G may be a single-layer structure or a multi-layer structure and formed of amorphous silicon, polycrystalline silicon, one or more kinds of metals, metal nitrides, metal silicides, conductive metal oxides, or a combination thereof. In some embodiments, the metals may include, but are not limited to tungsten (W), titanium (Ti), tantalum (Ta), platinum (Pt). In some embodiments, the metal nitrides may include, but are not limited to, titanium nitride (TiN) and tantalum nitride (TaN). In some embodiments, the metal silicides may include, but are not limited to tungsten silicide (WSiₓ). In some embodiments, the gate electrode 220G may selectively include dopants of the second conductivity type. For example, when the silicon carbide substrate 100 is an N-type silicon carbide substrate 100, the gate electrode 220G is a P-type gate electrode 220G. Furthermore, the dopant with the second conductivity type may include aluminum (Al), boron (B), boron difluoride (BF₂) or other suitable dopants.

In some embodiments, the gate electrode 220G embedded in the second epitaxial layer 202, the first epitaxial layer 200 and the silicon carbide substrate 100 may be electrically connected to an external circuit (not shown) through a contact feature (not shown) disposed above the top surface 202T of the second epitaxial layer 202.

The first type semiconductor component HVD of the semiconductor device 500 also includes a shielding dielectric layer 224S and an electrode 230F. As shown in FIG. 1, the shielding dielectric layer 224S and the electrode 230F are disposed in the second epitaxial layer 202 in the first active region 400. The shielding dielectric layer 224S and the electrode 230F are located directly above the gate structure 222 and extend toward the top surface 202T of the second epitaxial layer 202 in the direction 310.

The shielding dielectric layer 224S may have an outer sidewall adjacent to the second epitaxial layer 202 and an inner sidewall adjacent to the electrode 230F. The gate dielectric layer 216 may have an outer sidewall adjacent to the second epitaxial layer 202 and an inner sidewall adjacent to the gate electrode 220G. In some embodiments, the outer side-wall of the shielding dielectric layer 224S may be aligned with the outer sidewall of the gate dielectric layer 216. In the direction 300, a thickness T2 between the inner and outer side-walls of the shielding dielectric layer 224S may be greater than a thickness T1 between the inner and outer sidewalls of the gate dielectric layer 216. The thickness T2 of the shielding dielectric layer 224S is sufficient to withstand the operating voltage (i.e., the voltage difference between the emitter and the collector (or the source and the drain)) of the resulting first-type semiconductor component HVD. Therefore, the inner sidewall of the shielding dielectric layer 224S may not be aligned with the inner sidewall of the gate dielectric layer 216. Furthermore, the inner sidewall of the shielding dielectric layer 224S may be directly above the top surface 220GT of the gate electrode 220G.

In some embodiments, the shielding dielectric layer 224S may include silicon oxide, another suitable semiconductor oxide material, or a combination thereof. In some embodiments, the shielding dielectric layer 224S and the gate dielectric layer 216 may be made of the same or different materials according to actual requirements of products. When the shielding dielectric layer 224S and the gate dielectric layer 216 are both made of the same material, the interface between them is not obvious. In some embodiments, the shielding dielectric layer 224S may be formed using a conformably deposition process or another suitable process. In some embodiments, the deposition process may be a physical vapor deposition (PVD) process, a chemical vapor deposition (CVD) process, a plasma-enhanced chemical vapor deposition (PECVD), another suitable process, or a combination thereof.

The electrode 230F may be located on the shielding dielectric layer 224S. Furthermore, the shielding dielectric layer 224S may cover the top surface 220GT of the gate electrode 220G and surround the electrode 230F. The bottom surface of the electrode 230F close to the gate electrode 220G is separated from the gate electrode 220G by the shielding dielectric layer 224S. In some embodiments, the electrode 230F may be electrically connected to the silicon carbide substrate 100.

Since the outer sidewall of the shielding dielectric layer 224S may be aligned with the outer sidewall of the gate dielectric layer 216, and the thickness T2 between the inner and outer sidewalls of the shielding dielectric layer 224S may be greater than the thickness T1 between the inner and outer sidewalls of the gate dielectric layer 216, the width W1 of the gate electrode 220G may be greater than the width W2 of the electrode 230F in the direction 300.

In some embodiments, the electrode 230F may not only reduce the gate-to-drain (collector) capacitance (Cgd) to improve the switching characteristics of the first type semi-conductor component HVD, but also has a function of field plate to make the electric field distribution of the gate dielectric layer 216 close to the top surface 220GT of the gate electrode 220G relatively uniform and increase the breakdown voltage to improve the reliability of the gate dielectric layer 216.

In some embodiments, the electrode 230F may include the same or different material as the gate electrode 220G. In some embodiments, the electrode 230F may option-ally include dopants of the second conductivity type. For example, when the silicon carbide substrate 100 is an N-type silicon carbide substrate 100, the electrode 230F may be a P-type electrode 230F. Furthermore, the dopant having the second conductivity type may include aluminum (Al), boron (B), boron difluoride (BF₂) or other suitable dopants.

The first type semiconductor component HVD also includes a dielectric layer 236R′. As shown in FIG. 1, the dielectric layer 236R′ may extend from the top surface 202T of the second epitaxial layer 202 in the first active region 400 into a portion of the first epitaxial layer 200 in the direction 310.

In some embodiments, the dielectric layer 236R′ may include silicon oxide, another suitable semiconductor oxide material, or a combination thereof. In some embodiments, the shielding dielectric layer 224S and the dielectric layer 236R′ may be made of the same or different materials according to actual requirements of products. In some embodiments, the dielectric layer 236R′ may be formed using a conformably deposition process or another suitable process. In some embodiments, the deposition process may include a physical vapor deposition (PVD) process, a chemical vapor deposition (CVD) process, a plasma-enhanced chemical vapor deposition (PECVD), another suitable process, or a combination thereof. In the applications of trench insulated gate bipolar transistors, the dielectric layer 236R′ may serve as a trench isolation dielectric layer 236R′ of the first type semiconductor component HVD.

The first contact feature 260 of the first type semiconductor component HVD extends from the top surface 202T of the second epitaxial layer 202 in the first active region 400, through the first epitaxial layer 200, and into the silicon carbide substrate 100 in the direction 310. As shown in FIG. 1, the first contact feature 260 and the gate structure 222 are spaced apart from each other in a direction 300 (a direction substantially parallel to the top surface 100T of the silicon carbide substrate 100, which may also serve as a lateral direction).

In some embodiments, the dielectric layer 236R′ surrounds a portion of the sidewall of the first contact feature 260, and the bottom 260B of the first contact feature 260 protrudes from the bottom surface 236RB of the dielectric layer 236R′ and extends into the silicon carbide substrate 100. The dielectric layer 236R′ may have an outer sidewall adjacent to the second epitaxial layer 202 and an inner sidewall adjacent to the first contact feature 260. In the direction 300, a thickness T3 between the inner and outer sidewalls of the dielectric layer 236R′ may be equal to a thickness T2 between the inner and outer sidewalls of the shielding dielectric layer 224S. The thickness T3 of the dielectric layer 236R′ is sufficient to withstand the operating voltage (i.e., the voltage difference between the emitter and the collector (or the source and the drain)) of the resulting first type semiconductor component HVD.

The bottom portion 260B of the first contact feature 260 is electrically connected to the silicon carbide substrate 100 and the first epitaxial layer 200 simultaneously. In the applications of trench insulated gate bipolar transistors, the first contact feature 260 may serve as an emitter (source) contact feature of the first type semiconductor component HVD. In some embodiments, the first contact feature 260 may be electrically connected to the electrode 230F. In some embodiments, the first contact feature 260 may extend to the edge of the semiconductor device 500 and be electrically connected to an external circuit (not shown) through an interconnect structure (not shown) disposed above the top surface 202T of the second epitaxial layer 202.

In some embodiments, the first contact feature 260 may include a metal silicide (not shown), a first contact barrier layer 252S, and a first contact conductive layer 254S. The metal silicide is located at the bottom 260B of the first contact feature 260, which can cover and physically contact the silicon carbide substrate 100 and the first epitaxial layer 200. The first contact barrier layer 252S and the first contact conductive layer 254S thereon cover the metal silicide.

In some embodiments, the metal silicide includes, for example, tungsten silicide, titanium silicide, cobalt silicide, nickel silicide, platinum silicide, erbium silicide, another suitable metal silicide, or a combination thereof. In some embodiments, the metal layer may be entirely deposited using a deposition processes including chemical vapor deposition (CVD) (e.g., low pressure vapor deposition (LPCVD) or plasma-enhanced chemical vapor deposition (PECVD)), physical vapor deposition (PVD) (e.g., resistance heating evaporation, electron beam evaporation, or sputtering), electroplating, atomic layer deposition (ALD), another suitable process, or a combination thereof. Next, an annealing process is performed to make the metal layer of the silicon carbide substrate 100 and the first epitaxial layer 200 below the bottom surface 236RB of the dielectric layer 236R′ react with the semiconductor material to form a metal silicide. Thereafter, the unreacted metal layer is removed.

As shown in FIG. 1, the first contact barrier layer 252S extends from the top surface 202T of the second epitaxial layer 202 in the first active region 400, through the first epitaxial layer 200, and into the silicon carbide substrate 100 in the direction 310. In some embodiments, the first contact barrier layer 252S may be used to prevent a subsequently formed first contact conductive layer 254S from diffusing into the first epitaxial layer 200, the second epitaxial layer 202, and the silicon carbide substrate 100. The material of the first contact barrier layer 252S may include titanium (Ti), titanium nitride (TiN), tantalum (Ta), tantalum nitride (TaN), cobalt (Co), another suitable barrier material, or a combination thereof. In some embodiments, the contact barrier layer may be formed by a chemical vapor deposition (CVD) process, an atomic layer deposition (ALD) process, a physical vapor deposition (PVD) process, another suitable process, or a combination thereof.

In some embodiments, the first contact conductive layer 254S of the first contact feature 260 is located on the metal silicide and the first contact barrier layer 252S. Furthermore, the sidewall of the first contact conductive layer 254S and the bottom surface of the first contact conductive layer 254S close to the silicon carbide substrate 100 are surrounded by the first metal silicide 252S. In some embodiments, the first contact conductive layer 254S may be a single-layer structure or a multi-layer structure. The material of the first contact conductive layer 254S may include tungsten (W), aluminum (Al), copper (Cu), titanium (Ti), tantalum (Ta), titanium nitride (TiN), tantalum nitride (TaN), nickel silicide (NiSi), cobalt silicide (CoSi), another suitable metal, or a combination thereof. In some embodiments, the first contact conductive layer 254S may be formed by using a chemical vapor deposition (CVD) process, an atomic layer deposition (ALD) process, a physical vapor deposition (PVD) process, another suitable process, or a combination thereof.

The first type semiconductor component HVD also includes a doped region 234. As shown in FIG. 1, the doped region 234 is located in a portion of the first epitaxial layer 200 below the bottom surface 236RB of the dielectric layer 236R′ and surrounds a portion of the bottom 260B of the first contact feature 260. In some embodiments, the doped region 234 may be in contact with the top surface 100T of the silicon carbide substrate 100, or extend into a portion of the silicon carbide substrate 100 in the direction 310. In the direction 310, the bottom surface 234B of the doped region 234 may be located above the bottom surface 220GB of the gate electrode 220G (closer to the top surface 202T of the second epitaxial layer 202).

In some embodiments, the doped region 234 may be doped with dopants to have a second conductivity type. For example, when the silicon carbide substrate 100 is an N-type silicon carbide substrate 100, the doped region 234 is a P-type doped region 234. Moreover, the doping concentration of the doped region 234, for example, 10¹⁹-10²¹ atoms/cm³, is greater than the doping concentration of the first epitaxial layer 200. For example, the doped region 234 is a P-type heavily doped (P+) region 234 to serve as a pick-up doped region of the first epitaxial layer 200.

The first type semiconductor component HVD also includes a doped region 248. As shown in FIG. 1, the doped region 248 is located in the second epitaxial layer 202 in the first active region 400 and above the gate structure 222 and the electrode 230F. In some embodiments, the doped region 248 may be doped with dopants to have the first conductivity type. For example, when the silicon carbide substrate 100 is an N-type silicon carbide substrate 100, the doped region 248 is an N-type doped region 248. Furthermore, the doping concentration of the doped region 248, for example, 10¹⁷-10¹⁸ atoms/cm³, is greater than the doping concentration of the second epitaxial layer 202. In the applications of trench insulated gate bipolar transistors, the doped region 248 may serve as a buffer region of the second epitaxial layer 202. Through the arrangement of the doped region 248, the thickness of the second epitaxial layer 202 (the drift region) can be reduced while maintaining the same withstand voltage of the first type semiconductor component HVD, thereby reducing the ON-state voltage drop and the turn-off time.

The first type semiconductor component HVD also includes a doped region 250. As shown in FIG. 1, the doped region 250 is located on the doped region 248 and is close to the top surface 202T of the second epitaxial layer 202. In some embodiments, the doped region 250 may be doped with dopants to have a second conductivity type. For example, when the silicon carbide substrate 100 is an N-type silicon carbide substrate 100, the doped region 250 is a P-type doped region 250. Furthermore, the doping concentration of the doped region 250 is about 10¹⁹-10²¹ atoms/cm³. For example, the doped region 250 is a P-type heavily doped (P+) region 250. In the applications of trench insulated gate bipolar transistors, the doped region 250 may serve as the collector region (or the drain region) of the first type semiconductor component HVD. In some embodiments, the doped region 248 between the second epitaxial layer 202 (the drift region) and the doped region 250 (the collector region) may also affect the injection efficiency of the doped region 250 (the collector region).

The semiconductor device 500 also includes an interlayer dielectric layer 262. The interlayer dielectric layer 262 is disposed on the top surface 202T of the second epitaxial layer 202 and exposes a portion of the doped region 250. In some embodiments, the interlayer dielectric layer 262 may include silicon oxide, silicon nitride, silicon oxynitride, phosphosilicate glass (PSG), borophosphosilicate glass (BPSG), or a combination thereof. When the interlayer dielectric layer 262, the shielding dielectric layer 224S, the gate dielectric layer 216, and the dielectric layer 236R′ include the same material, the interfaces between the above elements are not obvious. In some embodiments, the interlayer dielectric layer 262 may be formed by using a conformably deposition process, an oxidation process, another suitable process, and a subsequent patterning process. In some embodiments, the oxidation process may be a thermal oxidation process or another suitable process. In some embodiments, the deposition process may be a physical vapor deposition (PVD) process, a chemical vapor deposition (CVD) process, a plasma-enhanced chemical vapor deposition (PECVD), another suitable process, or a combination thereof.

The first type semiconductor component HVD also includes a second contact feature 270. As shown in FIG. 1, the second contact feature 270 is disposed on the second epitaxial layer 202 in the first active region 400. The second contact feature 270 passes through the interlayer dielectric layer 262 from above the interlayer dielectric layer 262 in the direction 310 to cover and electrically connect the doped region (the collector region) 250. In the applications of trench insulated gate bipolar transistors, the second contact feature 270 may serve as a collector contact feature of the first type semiconductor component HVD.

Similar to the first contact feature 260, the second contact feature 270 may include a metal silicide (not shown), a second contact barrier layer 266D and a second contact conductive layer 268D. In some embodiments, the metal silicide may cover and physically contact the doped region 250. The second contact barrier layer 266D and the second contact conductive layer 268D thereon cover the metal silicide and pass through the interlayer dielectric layer 262. Furthermore, the sidewall of the second contact conductive layer 268D and the bottom surface of the second contact conductive layer 268D close to the second epitaxial layer 202 are surrounded by the second contact barrier layer 266D.

In some embodiments, the metal silicide of the first contact feature 260 and the metal silicide of the second contact feature 270 may include the same or similar materials and processes. In some embodiments, the first contact barrier layer 252S and the second contact barrier layer 266D include the same or similar materials and processes. In some embodiments, the first contact conductive layer 254S and the second contact conductive layer 268D may include the same or similar materials and processes.

The first type semiconductor component HVD also includes a third contact feature 280. As shown in FIG. 1, the third contact feature 280 is disposed on the bottom surface 100B of the silicon carbide substrate 100. Furthermore, the third contact feature 280 may cover and electrically connect the silicon carbide substrate (the emitter region) 100. In the applications of trench insulated gate bipolar transistors, the third contact feature 280 may serve as an emitter contact feature of the first type semiconductor component HVD. In addition, the third contact feature 280 may be electrically connected to the first contact feature 260 and the electrode 230F through other internal connections (not shown). In some embodiments, the third contact feature 280 may have a structure similar to that of the first contact feature 260 and the second contact feature 270.

As shown in FIG. 1, the semiconductor device 500 also includes a metal layer 290. The metal layer 290 is disposed on the second epitaxial layer 202 and the interlayer dielectric layer 262 in the first active region 400. The metal layer 290 covers the second contact feature 270, and is in physical and electrical contact with the second contact feature 270. The metal layer 290 may serve as a top metal layer of the final semiconductor device 500. The metal layer 290 of the first active region 400 may be electrically connected to the doped region 250 through the second contact feature 270. In the applications of trench insulated gate bipolar transistors, the metal layer 290 may serve as a collector metal layer 290.

In some embodiments, the metal layer 290 may include copper, silver, gold, aluminum, tungsten, another suitable metal material, or a combination thereof. In some embodiments, the metal layer 290 may include the same material, or different materials. In some embodiments, the metal layer 290 may be formed by a deposition process and a subsequent patterning process. In some embodiments, the deposition process may include a physical vapor deposition (PVD) process, a chemical vapor deposition (CVD) process, another suitable process, or a combination thereof.

In some embodiments, when the first type semiconductor component HVD is a trench insulated gate bipolar transistor, the gate structure 222 forms the gate of the trench insulated gate bipolar transistor, the silicon carbide substrate 100 forms the emitter of the trench insulated gate bipolar transistor, and the third doped region 250 forms the collector of the trench insulated gate bipolar transistor. The first contact feature 260 and the third contact feature 280 may serve as emitter contact features of the trench insulated gate bipolar transistor. The second contact feature 270 may serve as a collector contact feature of the trench insulated gate bipolar transistor.

In some embodiments, the first type semiconductor component HVD of the semiconductor device 500 may be easily integrated with semiconductor elements having different channel length directions and/or different operating voltages. For example, the first type semiconductor component HVD may be further integrated with a second type semi-conductor component LVD such as a low voltage lateral device such as a lateral metal-oxide-semiconductor field-effect transistor (lateral MOSFET). In some embodiments, the silicon carbide substrate 100 of the semiconductor device 500 may also include a second active region 410. In some embodiments, the dielectric layer 236R′ and the first contact feature 260 passing therethrough may be located at the interface between the first active region 400 and the second active region 410. In addition, the dielectric layer 236R′ may serve as a trench isolation dielectric layer to electrically isolate components disposed in the first active region 400 and the second active region 410 from each other. In addition, since the first contact feature 260 is electrically connected to h the silicon carbide substrate 100 (the emitter region) and the first epitaxial layer 200 simultaneously, and the second contact feature 270 is electrically connected to the doped region 250 (the collector region) on the second epitaxial layer 202, a reverse bias is applied to the PN junction formed by the first epitaxial layer 200 and the second epitaxial layer 202, resulting in junction isolation. In addition, the components disposed in the first active region 400 and the second active region 410 may be electrically isolated from each other.

The second active region 410 may be an active region provided for low voltage lateral devices such as complementary metal-oxide-semiconductor field-effect transistors formed therein. Two second type semiconductor components LVD (such as a complementary metal-oxide-semiconductor field-effect transistor) of different conductivity types are used as an example for the structural description in the low voltage level device active region. However, any number of second type semiconductor components LVD may be disposed in the low voltage level device active region and is not limited to the embodiments described herein.

The second type semiconductor component LVD of the semiconductor device 500 is disposed in the second active region 410. In some embodiments, the second type semiconductor component LVD may include a semiconductor component LVD1. In some embodiments, the semiconductor component LVD1 may include a well region 312A, a gate structure 320A, a doped region 324A, a doped region 326A, and a doped region 328A.

The well region 312A is located in the second epitaxial layer 202 in the second active region 410. In some embodiments, the well region 312A may be adjacent to the dielectric layer 236R′ and may be separated from the gate structure 222 by the first contact feature 260 and the dielectric layer 236R′. In some embodiments, the well region 312A may be doped with dopants to have the first conductivity type or the second conductivity type. For example, when the silicon carbide substrate 100 is an N-type silicon carbide substrate 100, the well region 312A is an N-type well region 312A or a P-type well region 312A. Furthermore, the doping concentration of the well region 312A is, for example, about 10¹⁵-10¹⁶ atoms/cm³. In this embodiment, the well region 312A may have the second conductivity type, such as a P-type well region 312A. In the applications of the lateral MOSFET, the well region 312A may serve as the bulk of the semiconductor component LVD1.

The gate structure 320A is disposed on the well region 312A and extends in the direction 300. In some embodiments, the gate structure 320A includes a gate dielectric layer (not shown) disposed on the second epitaxial layer 202, a gate electrode layer (not shown) disposed above the gate dielectric layer, and gate spacers (not shown) disposed on the side-walls of the gate dielectric layer and the gate electrode layer.

In some embodiments, the gate dielectric layer includes silicon oxide, silicon nitride, silicon oxynitride, a high-k dielectric material, another suitable dielectric material, or a combination thereof. The high dielectric constant material is, for example, hafnium oxide, hafnium silicon oxide, hafnium silicon oxynitride, hafnium tantalum oxide, hafnium titanium oxide, hafnium zirconium oxide, zirconium oxide, aluminum oxide, hafnium oxide-aluminum oxide alloy, another suitable high dielectric constant material, or a combination thereof. In some embodiments, an oxidation process, a deposition process or another suitable process may be used to form a gate dielectric layer on the second epitaxial layer 202. In some embodiments, the gate electrode layer includes polycrystalline silicon, amorphous silicon, metal (e.g., tungsten, titanium, aluminum, copper, molybdenum, nickel, platinum, other suitable metals, or a combination thereof), metal alloys, metal nitrides (e.g., tungsten nitride, molybdenum nitride, titanium nitride, tantalum nitride, other suitable metal nitrides, or a combination thereof), metal oxides (ruthenium oxide, indium tin oxide, other suitable metal oxides, or a combination thereof), other suitable materials, or a combination thereof. In some embodiments, the gate electrode layer may be doped by in-situ doping. In some embodiments, the gate spacer includes silicon oxide, silicon nitride, silicon oxynitride, a low-k material, another suitable dielectric material, or a combination thereof. In some embodiments, an oxidation process, a deposition process or another suitable process may be used to form gate spacers on the sidewalls of the gate dielectric layer and the gate electrode layer.

The doped region 324A and the doped region 326A are located on the well region 312A and on two opposite sides of the gate structure 320A. In some embodiments, the doped region 324A and the doped region 326A may be doped with dopants to have the same conductivity type. Furthermore, the conductivity types of the doped region 324A and the doped region 326A may be the opposite of the conductivity type of the well region 312A. For example, when the well region 312A has the second conductivity type (e.g., the P-type well region 312A), the doped region 324A and the doped region 326A may have the first conductivity type (e.g., the N-type doped region 324A and the N-type doped region 326A). In the present embodiment, the doping concentration of the doped region 324A and the doped region 326A, for example, 10¹⁹-10²¹ atoms/cm³, is greater than the doping concentration of the second epitaxial layer 202. For example, when the second epitaxial layer 202 is an N-type lightly doped (N−) epitaxial layer 202, the doped region 324A and the doped region 326A are N-type heavily doped (N+) regions 324A and N-type heavily doped (N+) regions 326A. In the applications of the lateral MOSFET, the doped region 324A and the doped region 326A may serve as the source region and the drain region of the semiconductor component LVD1.

The semiconductor component LVD1 may also include a plurality of doped regions LDN. The doped regions LDN are located on the well region 312A below the gate structure 320A and are respectively adjacent to the doped region 324A and the doped region 326A. In some embodiments, the doped regions LDN may be doped with dopants to have the same conductivity type. Furthermore, the conductivity type of the doped region LDN may be the same as the conductivity type of the doped region 324A and the doped region 326A (for example, N-type doped regions LDN). The doping concentration of the doped region LDN, for example, 1×10¹⁸-6×10¹⁸ atoms/cm³, is less than the doping concentrations of the doped region 324A and the doped region 326A. In the applications of the lateral MOSFET, the doped region LDN may serve as a lightly doped source/drain (LDD) region LDN of the semiconductor component LVD1.

The doped region 328A is located on the well region 312A. In some embodiments, the doped region 328A may be adjacent to the doped region 324A. In some embodiments, the doped region 328A may be doped with dopants to have the same conductivity type as the well region 312A. For example, when the well region 312A has the second conductivity type (e.g., the P-type well region 312A), the doped region 328A may have the second conductivity type (e.g., the P-type doped region 328A). Furthermore, the doping concentration of the doped region 328A, for example, 10¹⁹-10²¹ atoms/cm³, is greater than the doping concentration of the well region 312A. For example, when the well region 312A is a P-type well region 312A, the doped region 328A is a P-type heavily doped (P+) region 328A to serve as a pick-up doped region of the well region 312A.

The semiconductor component LVD1 also includes contact features 330A, 334A, 336A, and 338A. The contact features 330A, 334A, 336A, and 338A are disposed on the second epitaxial layer 202 in the second active region 410. The contact features 330A, 334A, 336A, and 338A pass through the interlayer dielectric layer 262 in the direction 310 to respectively cover and electrically connect the gate structure 320A, the doped region 324A, the doped region 326A and the doped region 328A. In the applications of the lateral MOSFETs, the contact features 330A, 334A, 336A, and 338A may serve as the gate contact feature 330A, the source and drain contact features 334A and 336A, and the bulk contact feature 338A of the semiconductor component LVD1, respectively. In some embodiments, the contact features 330A, 334A, 336A, 338A may have the same or similar structure as the second contact feature 270 and may be formed simultaneously.

The semiconductor component LVD1 also includes metal layers 340A, 344A, 346A, and 348A. The metal layers 340A, 344A, 346A, and 348A in the second active region 410 may cover the contact features 330A, 334A, 336A, and 338A. In addition, the metal layers 340A, 344A, 346A, and 348A may be in physical and electrical contact with the contact features 330A, 334A, 336A, and 338A. The metal layers 340A, 344A, 346A, 348A and the metal layer 290 may all belong to the top metal layer of the resulting semiconductor component LVD1. The metal layers 340A, 344A, 346A, 348A in the second active region 410 may be electrically connected to the gate structure 320A, the doped region 324A, the doped region 326A and the doped region 328A through the contact features 330A, 334A, 336A, 338A. In the applications of lateral MOSFETs, the metal layers 340A, 344A, 346A, and 348A may serve as the gate metal layer 340A, the source and drain metal layers 344A and 346A, and the bulk metal layer 348A of the semiconductor component LVD1, respectively. In some embodiments, the metal layers 340A, 344A, 346A, and 348A may have the same or similar structure as the metal layer 290 and may be formed simultaneously.

The second type semiconductor component LVD may also include a semiconductor component LVD2. As shown in FIG. 1, the semiconductor component LVD2 may be disposed side by side with the semiconductor component LVD1 in the direction 300, and may be separated from the semiconductor component LVD1 by an isolation feature 204 (e.g., a shallow trench isolation feature (STI)). In this embodiment, the semiconductor component LVD1 and the semiconductor component LVD2 may have the same or similar structure, but have opposite conductivity types. In some embodiments, the semiconductor component LVD2 may include a well region 312B, a gate structure 320B, a doped region 324B, a doped region 326B, and a doped region 328B. In some embodiments, well region 312B may be adjacent to well region 312A. Furthermore, the isolation feature 204 may be disposed at the interface between the well region 312A and the well region 312B to serve as an electrical isolation feature between the semiconductor components LVD1 and LVD2. In some embodiments, well region 312A and well region 312B may have the same or similar doping concentration and depth (in the direction 310), and have opposite conductivity types. In this embodiment, the well region 312B has a first conductivity type, such as an N-type well region 312B. In the applications of lateral MOSFETs, the well region 312B may serve as the bulk of the semiconductor component LVD2.

The gate structure 320B is disposed on the well region 312A and extends in the direction 300. In some embodiments, the gate structure 320A and the gate structure 320B may have the same or similar structures.

The doped region 324B and the doped region 326B are located on the well region 312B and on two opposite sides of the gate structure 320B. In some embodiments, the doped regions 324A and 326A may have the same or similar doping concentrations as the doped regions 324B and 326B, but have opposite conductivity types. In the present embodiment, the doped region 324B and the doped region 326B have the second conductivity type, such as a P-type heavily doped (P+) region 324B and a P-type heavily doped (P+) region 326B. In the applications of the lateral MOSFET, the doped region 324B and the doped region 326B may serve as the source region and the drain region of the semiconductor component LVD2.

The semiconductor component LVD2 may also include a plurality of doped regions LDP. The doped regions LDP are located on the well region 312B below the gate structure 320B. The doped regions LDP are adjacent to the doped region 324B and the doped region 326B respectively. In some embodiments, the doped regions LDN and the doped regions LDP may have the same or similar doping concentrations but opposite conductivity types. Furthermore, the conductivity type of the doped regions LDP may be the same as the conductivity type of the doped region 324B and the doped region 326B (e.g., P-type doped regions LDP). In the applications of the lateral MOSFETs, the doped regions LDP may serve as the lightly doped source and drain regions LDP of the semiconductor component LVD2.

The doped region 328B is located on the well region 312B. In some embodiments, the doped region 328B may be adjacent to the doped region 324B. In some embodiments, the doped region 328A and the doped region 328B may have the same or similar doping concentrations, but opposite conductivity types. In this embodiment, the doped region 328B has a first conductivity type, for example, an N-type heavily doped (N+) region 328B. In the applications of lateral MOSFETs, it may serve as the pick-up doped region of the well region 312B.

The semiconductor component LVD2 also includes contact features 330B, 334B, 336B, and 338B. The contact features 330B, 334B, 336B, and 338B are disposed on the second epitaxial layer 202 of the second active region 410. The contact features 330B, 334B, 336B, and 338B pass through the interlayer dielectric layer 262 in the direction 310 to respectively cover and electrically connect the gate structure 320B, the doped region 324B, the doped region 326B, and the doped region 328B. In the applications of lateral MOSFETs, the contact features 330B, 334B, 336B, and 338B may serve as the gate contact feature 330B, the source and drain contact features 334B and 336B, and the bulk contact feature 338B of the semiconductor component LVD2, respectively. In some embodiments, the contact features 330B, 334B, 336B, 338B may have the same or similar structure as the second contact feature 270 and may be formed simultaneously.

The semiconductor component LVD2 also includes metal layers 340B, 344B, 346B, and 348B. The metal layers 340B, 344B, 346B, 348B in the second active region 410 may cover the contact features 330B, 334B, 336B, 338B, and be in physical and electrical contact with the contact features 330B, 334B, 336B, 338B. The metal layers 340B, 344B, 346B, and 348B may all belong to the top metal layer of the final semiconductor component LVD2. The metal layers 340B, 344B, 346B, and 348B in the second active region 410 may be electrically connected to the gate structure 320B, the doped region 324B, the doped region 326B, and the doped region 328B through the contact features 330B, 334B, 336B, and 338B. In the applications of lateral MOSFETs, the metal layers 340B, 344B, 346B, 348B may serve as the gate metal layer 340B, the source and drain metal layers 344B and 346B, and the bulk metal layer 348B of the semiconductor component LVD2, respectively. In some embodiments, the metal layers 340B, 344B, 346B, and 348B may have the same or similar materials and processes as the metal layer 290, and may be formed simultaneously.

In this embodiment, the second type semiconductor component LVD may be a complementary metal-oxide-semiconductor field-effect transistor (CMOS). The semiconductor component LVD1 may be a P-type metal-oxide-semiconductor field-effect transistor (PMOS), and the semiconductor component LVD2 may be an N-type metal-oxide-semiconductor field-effect transistor (NMOS). The gate structure 320A of the semiconductor component LVD1 forms the gate of a P-type metal-oxide-semiconductor field-effect transistor. The doped region 324A and the doped region 326A form the source and the drain of the P-type metal-oxide-semiconductor field-effect transistor. The well region 312A and the doped region 328A form the bulk of the P-type metal-oxide-semiconductor field-effect transistor. In addition, the gate structure 320B of the semiconductor component LVD2 forms the gate of the N-type metal-oxide-semiconductor field-effect transistor. The doped region 324B and the doped region 326B form the source and the drain of the N-type metal-oxide-semiconductor field-effect transistor. The well region 312B and the doped region 328B form the bulk of the N-type metal-oxide-semiconductor field-effect transistor.

In some embodiments, the channel region of the first type semiconductor component HVD and the channel region of the second type semiconductor component LVD may have different channel length directions. More specifically, the channel region of the first type semiconductor component HVD (e.g., the insulated gate bipolar transistor) is in the first epitaxial layer 200 close to the sidewall of the gate structure 222. In some embodiments, the channel length direction of the channel region of the first type semiconductor component HVD is substantially parallel to the direction 310 (i.e., the vertical channel direction). The channel region of the semiconductor component LVD1 of the second type semiconductor component LVD is in the well region 312A below the gate structure 320A and between the doped regions 324A and 326A. The channel region of the semiconductor component LVD2 is in the well region 312B below the gate structure 320B and between the doped regions 324B and 326B. The channel length directions of the channel regions of the semiconductor components LVD1 and LVD2 are substantially parallel to the direction 300 (i.e., the lateral channel direction). In this embodiment, the channel length direction of the first type semi-conductor component HVD and the channel length direction of the second type semiconductor component LVD are perpendicular to each other.

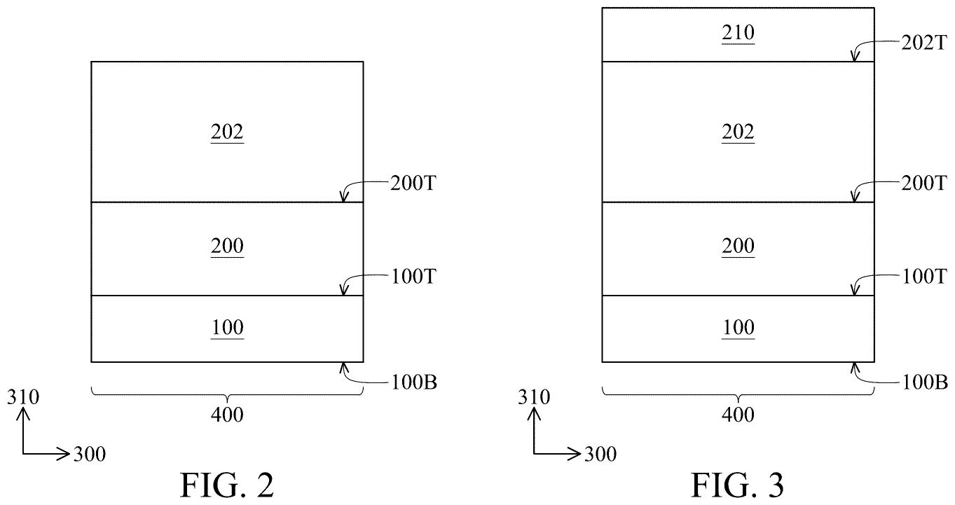

A method for forming a first type semiconductor component HVD of a semi-conductor device 500 in accordance with some embodiments of the disclosure will be described with reference to FIGS. 2 to 24. FIGS. 2 to 24 are cross-sectional views of intermediate stages of forming the first type semiconductor component HVD of the semiconductor device 500 of FIG. 1 in accordance with some embodiments of the disclosure, in which the reference numbers the same or similar to those in FIG. 1 denote the same or similar elements.

As shown in FIG. 2, a silicon carbide substrate 100 having a first conductivity type, for example, an N-type heavily doped (N+) silicon carbide substrate 100, is provided. In some embodiments, the silicon carbide substrate has at least a first active region 400.

Next, multiple epitaxial growth processes are performed to sequentially grow a first epitaxial layer 200 of the second conductivity type on the top surface 100T of the silicon carbide substrate 100, and a second epitaxial layer 202 of the first conductivity type on the top surface 200T of the first epitaxial layer 200. In some embodiments, the first epitaxial layer 200 is, for example, a P-type lightly doped (P−) silicon carbide epitaxial layer 200. The second epitaxial layer 202 is, for example, an N-type lightly doped (N−) silicon carbide epitaxial layer 202. In some embodiments, the epitaxial growth process includes metal organic chemical vapor deposition (MOCVD), plasma-enhanced chemical vapor deposition (PECVD), molecular beam epitaxy (MBE), hydride vapor phase epitaxy (HVPE), liquid phase epitaxy (LPE), chloride vapor phase epitaxy (Cl-VPE), another suitable epitaxial growth process, or a combination thereof.

Next, as shown in FIG. 3, a deposition process may be performed to form a mask layer 210 on the top surface 202T of the second epitaxial layer 202. In some embodiments, the mask layer 210 may be a single-layer structure or a multi-layer structure. In some embodiments, the mask layer 210 may include an insulating material such as silicon oxide.

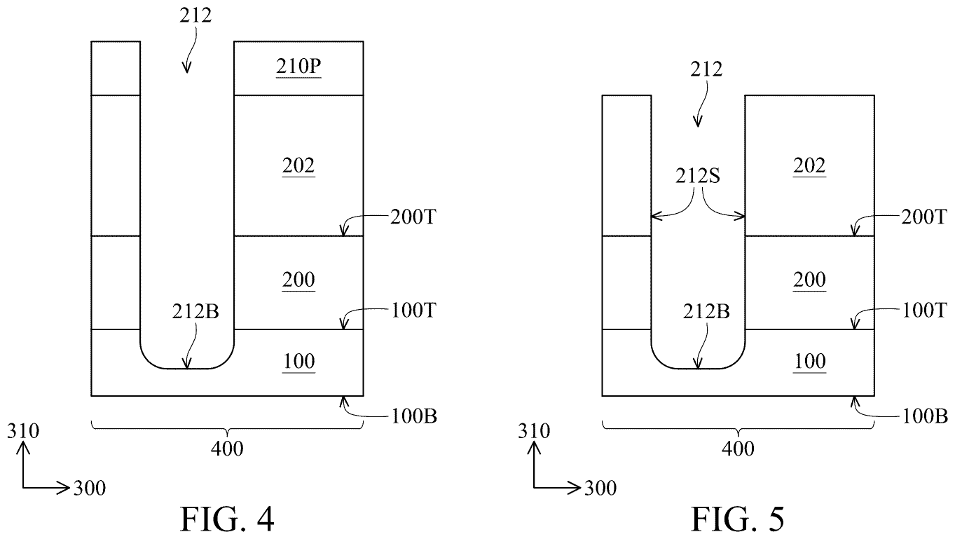

Next, as shown in FIG. 4, a lithography process and a subsequent patterning process are performed to remove a portion of the mask layer 210 to form a mask pattern 210P on the top surface 202T of the second epitaxial layer 202 to define a formation position of the trench 212. Afterwards, the mask pattern 210P is used as an etching mask to perform an etching process. The etching process removes the second epitaxial layer 202, the first epitaxial layer 200 and a portion of the silicon carbide substrate 100 not covered by the mask pattern 210P to form a trench 212 in the first epitaxial layer 200, the second epitaxial layer 202 and a portion of the silicon carbide substrate 100 in the first active region 400 in the direction 310. The trench 212 passes the first epitaxial layer 200 and the second epitaxial layer 202 in the direction 310. Furthermore, the bottom surface 212B of the trench 212 is located above the bottom surface 100B of the silicon carbide substrate 100 (the trench 212 does not penetrate the silicon carbide substrate 100). In the embodiment shown in FIG. 4, each of the unit cells of the first type semiconductor component HVD has one trench 212. In some embodiments, the etching process includes dry etching. Dry etching may include plasma etching, plasma-free gas etching, sputter etching, ion milling, reactive ion etching (RIE), neutral beam etch (NBE), inductive coupled plasma etch or another suitable process.

Next, as shown in FIG. 5, a selective etching process may be performed to remove the mask pattern 210P. Next, an oxidation process and a subsequent etching process may be performed to form a sacrificial oxide layer (SAC oxide layer) (not shown) on side-walls 212S and the bottom surface 212B of the trench 212. Then, an etching process is performed to remove the sacrificial oxide layer so that the sidewalls 212S and the bottom surface 212B of the trench 212 are exposed again. The oxidation process and etching process shown in FIG. 5 may remove the surface damage caused by the etching process (FIG. 4) for forming the trench 212.

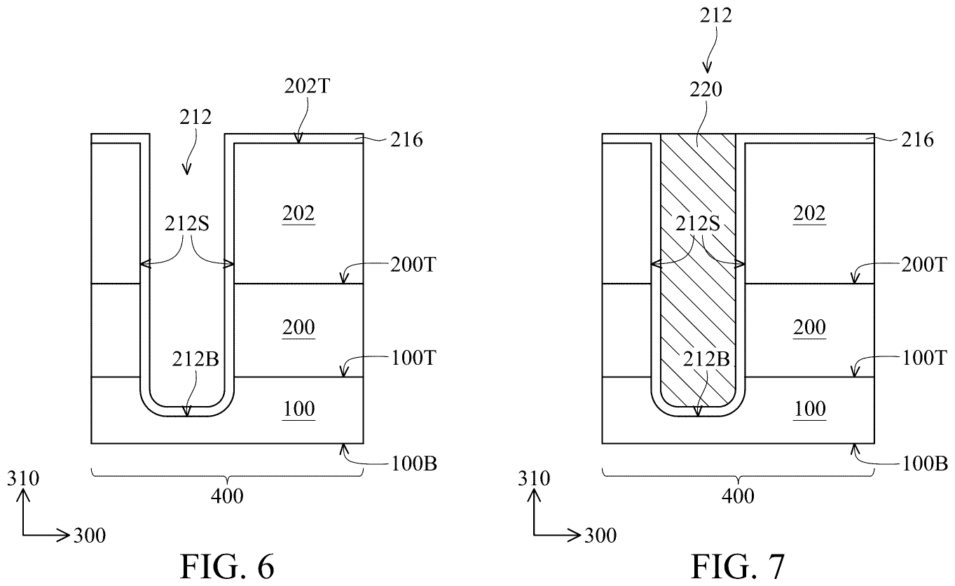

Next, as shown in FIG. 6, an oxidation process may be performed to conformally form a gate dielectric layer 216 in the trench 212. The oxidation process includes oxidizing the top surface 202T of the second epitaxial layer 202, and the sidewalls 212S and the bottom surface 212B of the trench 212 to form a gate dielectric layer 216 in the trench 212. In some embodiments, the gate dielectric layer 216 does not completely fill the trench 212.

Next, as shown in FIG. 7, a deposition process and a subsequent planarization process may be performed to entirely form an electrode material 220 on the second epitaxial layer 202. The electrode material 220 covers the gate dielectric layer 216 of the first active region 400. Furthermore, the electrode material 220 fills the trench 212 (FIG. 6). In some embodiments, the electrode material 220 is doped to have the second conductivity type (e.g., a P-type electrode material 220). The electrode material 220 may include polysilicon (e.g., doped polysilicon). In some embodiments, the deposition process may include metal organic chemical vapor deposition (MOCVD), sputtering, resistance heating evaporation, electron beam evaporation, or another suitable deposition process. In some embodiments, the planarization process includes a chemical mechanical polishing (CMP) process.

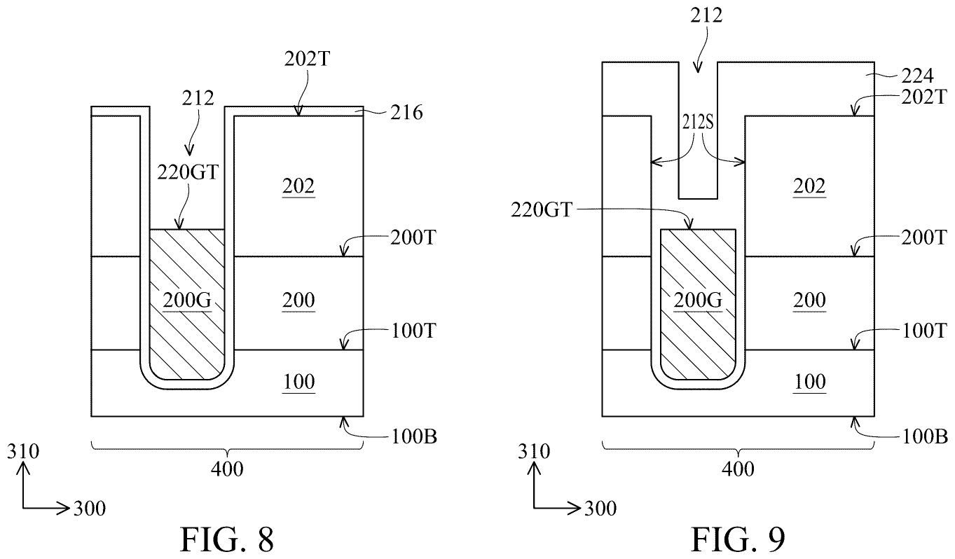

Next, as shown in FIG. 8, a selective etching process may be performed to remove a portion of the electrode material 220 (FIG. 7) from the upper portion of the trench 212 close to the top surface 202T of the second epitaxial layer 202, so as to form a gate electrode 220G in the trench 212. The gate electrode 220G fills the lower portion of the trench 212 away from the top surface 202T of the second epitaxial layer 202, and exposes the gate dielectric layer 216 at the upper portion of the trench 212. A top surface 220GT of the gate electrode 220G may be located above the top surface 200T of the first epitaxial layer 200. In some embodiments, the selective etching process includes dry etching.

Next, as shown in FIG. 9, a deposition process may be performed to conformally form a shielding dielectric layer 224 on the top surface 202T of the second epitaxial layer 202 and in the trench 212. The shielding dielectric layer 224 completely covers the top surface 220GT of the gate electrode 220G. Furthermore, the shielding dielectric layer 224 conformally covers the top surface 202T of the second epitaxial layer 202 and the gate dielectric layer 216 on the sidewalls 212S of the upper portion of the trench 212. When both the gate dielectric layer 216 and the shielding dielectric layer 224 include silicon oxide, the interface between the gate dielectric layer 216 and the shielding dielectric layer 224 is not obvious.

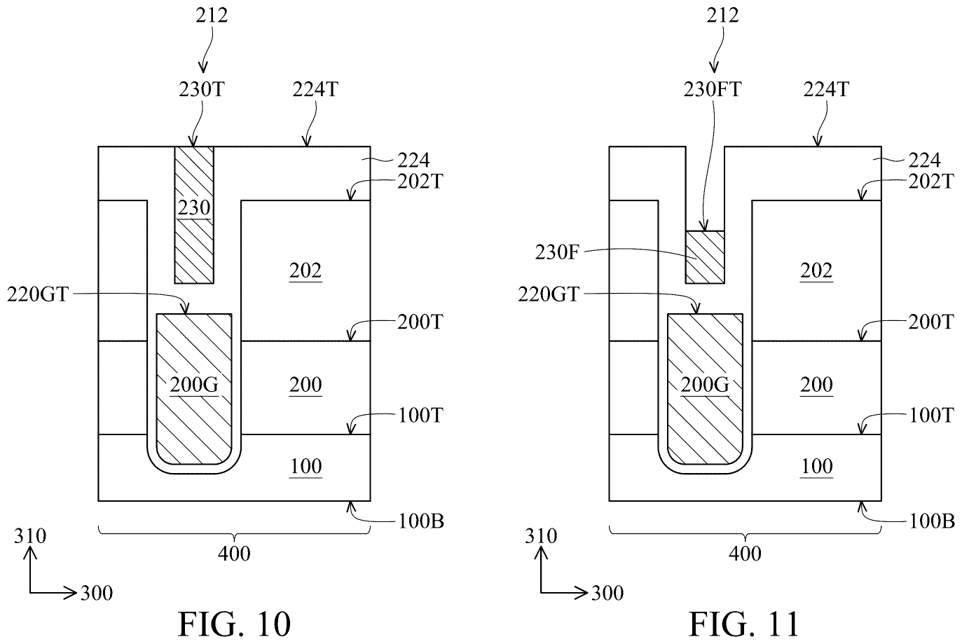

Next, as shown in FIG. 10, a deposition process and a subsequent planarization process may be performed to form a conductive material 230 in the trench 212. A top surface 230T of the conductive material 230 is aligned with a top surface 224T of the shielding dielectric layer 224. In some embodiments, the conductive material 230 may be formed of amorphous silicon, polycrystalline silicon, one or more kinds of metals, metal nitrides, metal silicides, conductive metal oxides, or a combination thereof. In some embodiments, the metals may include, but are not limited to, tungsten (W), titanium (Ti), tantalum (Ta), and platinum (Pt). In some embodiments, the metal nitrides may include, but are not limited to, titanium nitride (TiN) and tantalum nitride (TaN). In some embodiments, the metal silicides may include, but is not limited to, tungsten silicide (WSiₓ). In some embodiments, the deposition process may include metal organic chemical vapor deposition (MOCVD), sputtering, resistance heating evaporation, electron beam evaporation, or another suitable deposition process. In some embodiments, the planarization process includes a chemical mechanical polishing (CMP) process.

Next, as shown in FIG. 11, a photolithography process and a subsequent etch-back process may be performed to remove a portion of the conductive material 230 from the top surface 230T of the conductive material 230 (FIG. 10) in the first active region 400. The aforementioned lithography process may form a mask pattern (not shown) such as a photoresist pattern on the top surface 202T of the second epitaxial layer 202, and expose the first active region 400. Next, an etch-back process may be performed to remove a portion of the conductive material 230 located in the first active region 400 and close to the top surface 202T of the second epitaxial layer 202. After performing the etch-back process, an electrode 230F is formed on the shielding dielectric layer 224 in the trench 212. The electrode 230F is formed in the upper portion of the trench 212, but does not completely fill the upper portion of the trench 212. As shown in FIG. 11, a top surface 230FT of the electrode 230F may be located below a top surface 202T of the second epitaxial layer 202. In some embodiments, the etch-back process may be a selective etching process, such as dry etching.

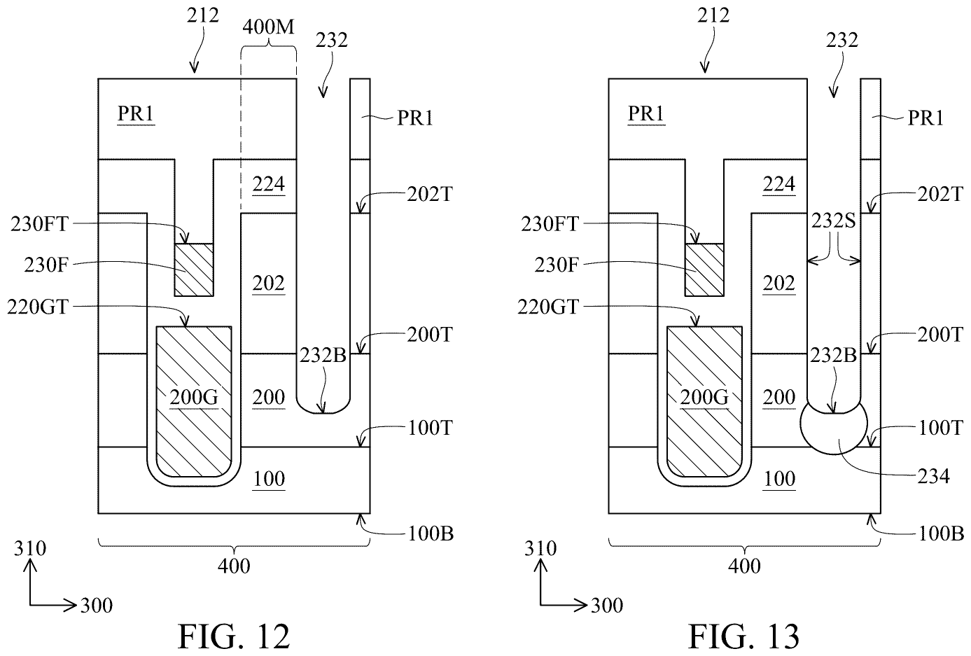

Next, as shown in FIG. 12, a lithography process may be performed to form a mask pattern PR1, such as a photoresist pattern, on the second epitaxial layer 202 in the first active region 400. The mask pattern PR1 covers a portion of the gate dielectric layer 216 (FIG. 8), the gate electrode 220G, a portion of the shielding dielectric layer 224 and the electrode 230F in the trench 212, and exposes a portion of the shielding dielectric layer 224 near the trench 212 and on the top surface 202T of the second epitaxial layer 202 from the mask pattern PR1 to define a formation position of a trench 232.

Next, the mask pattern PR1 is used as an etching mask to perform an etching process. The etching process removes the second epitaxial layer 202 and a portion of the first epitaxial layer 200 not covered by the mask pattern PR1 to form the trench 232 in the second epitaxial layer 202 and a portion of the first epitaxial layer 200 in the first active region 400 in the direction 310. The trench 232 passes through the second epitaxial layer 202 in the direction 310. Furthermore, the bottom surface 232B of the trench 232 is located above the bottom surface of the first epitaxial layer 200 (the top surface 100T of the silicon carbide substrate 100) (i.e., the trench 232 does not penetrate the first epitaxial layer 200).

In the embodiment shown in FIG. 12, each of the unit cells of the first type semiconductor component HVD has one trench 232. Furthermore, the trench 212 and the trench 232 are separated from each other in the direction 300 and define a mesa region 400M of the epitaxial layer 200. In some embodiments, the trench 212 and the trench 232 may be formed by the same or similar processes.

Next, as shown in FIG. 13, an ion implantation process may be performed to form a doped region 234 having the second conductivity type in the first epitaxial layer 200 (and in a portion of the silicon carbide substrate 100) exposed from the bottom surface 232B of the trench 232. After forming the doped region 234, the mask pattern PR1 is removed.

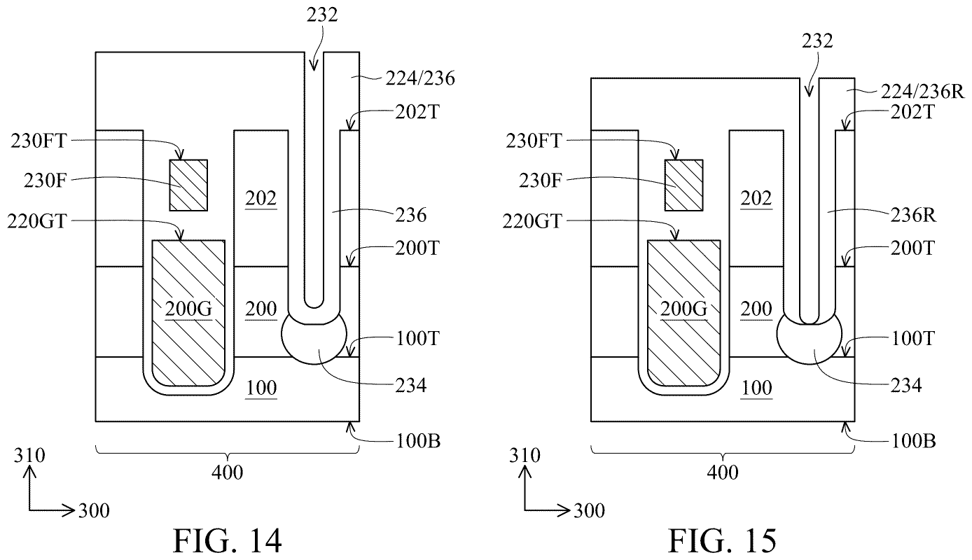

Next, as shown in FIG. 14, a deposition process may be performed to conformally form a dielectric layer 236 on the top surface 202T of the second epitaxial layer 202 and in the trench 232. The dielectric material layer 236 conformally covers sidewalls 232S and the bottom surface 232B of the trench 232 (FIG. 13). When both the shielding dielectric layer 224 and the dielectric layer 236 include silicon oxide, the interface between the shielding dielectric layer 224 and the dielectric layer 236 is not obvious.

Next, as shown in FIG. 15, a selective etching process may be performed to remove a portion of the dielectric layer 236 on the bottom surface 232B (FIG. 13) of the trench 232, thereby exposing a portion of the doped region 234. During the selective etching process, a portion of the dielectric layer 236 on the top surface 202T of the second epitaxial layer 202 and outside the trench 232 may be removed, so that the shielding dielectric layer 224 is exposed again. After performing the selective etching process, the remaining dielectric layer 236 is labeled as a dielectric layer 236R. In some embodiments, the selective etching process includes a blanket etching process.

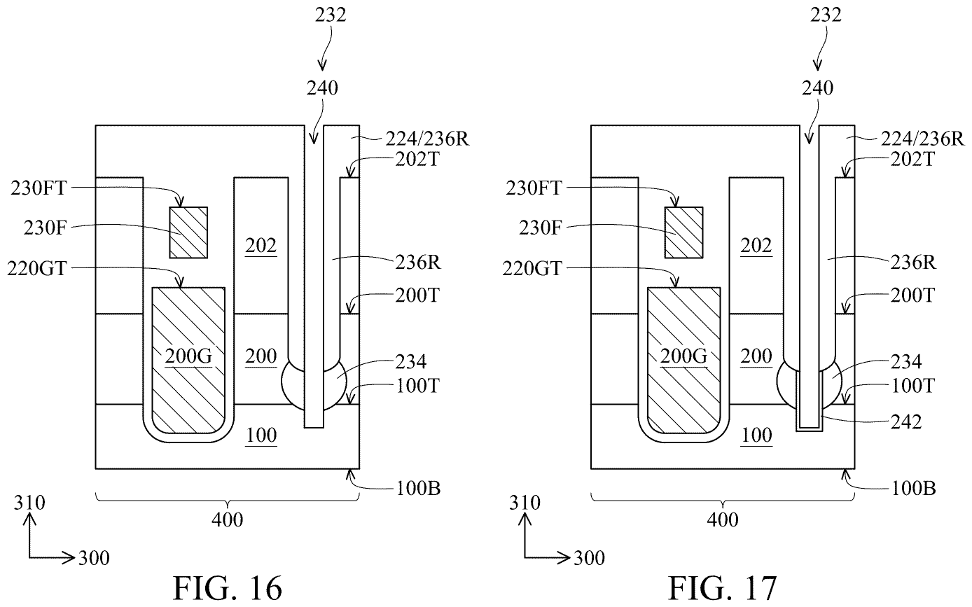

Next, as shown in FIG. 16, the shielding dielectric layer 224 and the dielectric layer 236R may be used as etching masks to perform a selective etching process. The selective etching process removes the first epitaxial layer 200 and the silicon carbide substrate 100 under the bottom surface 232B (FIG. 13) of the trench 232 to form a trench 240. In some embodiments, the trench 240 passes through the doped region 234 from the bottom surface 232B (FIG. 13) of the trench 232 into the silicon carbide substrate 100. Furthermore, the trench 240 passes through the doped region 234. In the direction 310, the trench 240 is located below the trench 232 and communicates with the trench 232.

Next, as shown in FIG. 17, an oxidation process may be performed to form a dielectric layer 242 on the first epitaxial layer 200 and the silicon carbide substrate 100 exposed from the trench 240. The oxidation process includes oxidizing the opposite sidewalls and the bottom surface of the trench 240 to form the dielectric layer 242. In some embodiments, the dielectric layer 242 does not completely fill the trench 240. In some embodiments, dielectric layer 242 may be silicon oxide.

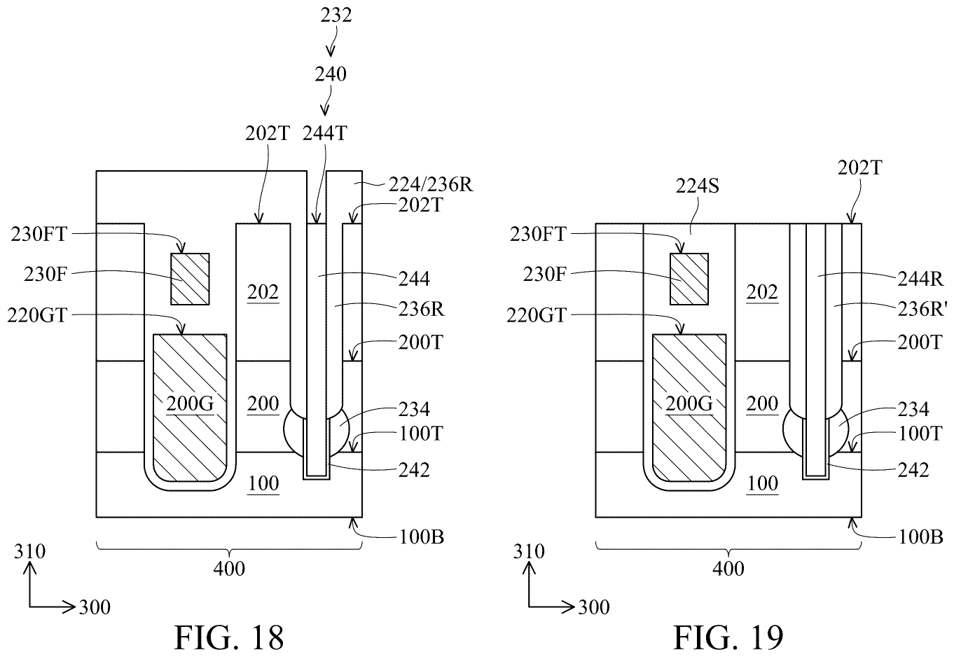

Next, as shown in FIG. 18, a deposition process and a subsequent etch-back process may be performed to form a dielectric layer 244 in the trench 232 and the trench 240. The top surface 244T of the dielectric layer 244 may be not lower than the top surface 202T of the second epitaxial layer 202. For example, the top surface 244T of the dielectric layer 244 may be aligned with or slightly higher than the top surface 202T of the second epitaxial layer 202. In some embodiments, the dielectric layer 242 and the dielectric layer 244 may be formed of different materials. For example, the dielectric layer 242 may be silicon oxide, and the dielectric layer 244 may be silicon nitride. The dielectric layer 244 may be used to fill the trenches 232 and 240 to prevent the slurry used in the subsequent planarization process from clogging the trenches 232 and 240 having a high aspect ratio. In some embodiments, the etch-back process may be a selective etching process, such as dry etching.

Next, as shown in FIG. 19, a planarization process may be performed to remove the gate dielectric layer 216, the shielding dielectric layer 224, and the dielectric layer 236R above the top surface 202T of the second epitaxial layer 202, so that the top surface 202T of the second epitaxial layer 202 is exposed. The planarization process may also remove the dielectric layer 244 above the top surface 202T of the second epitaxial layer 202. After performing the planarization process, the remaining dielectric layer 236R in the trenches 232 and 240 (FIG. 18) is labeled as dielectric layer 236R′, the remaining dielectric layer 244 is labeled as dielectric layer 244R. In addition, the remaining shielding dielectric layer 224 and dielectric layer 236R in the trench 212 (FIG. 12) are collectively labeled as shielding dielectric layer 224S. The top surfaces of the dielectric layer 236R′, the dielectric layer 244R, and the shielding dielectric layer 224S are coplanar with the top surface 202T of the second epitaxial layer 202. In some embodiments, the planarization process includes a chemical mechanical polishing (CMP) process.

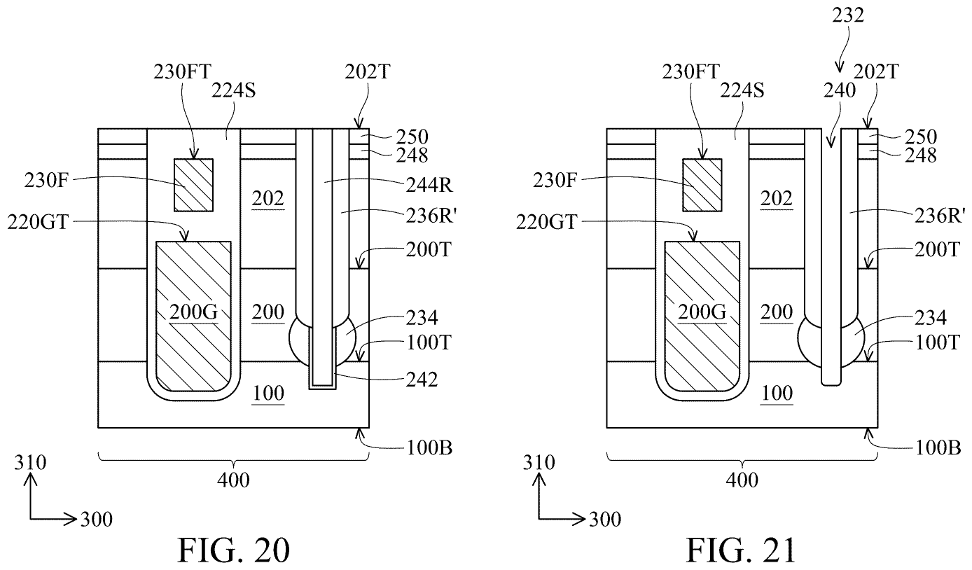

Next, as shown in FIG. 20, multiple ion implantation processes may be performed to form a doped region 248 having the first conductivity type (e.g., N-type) in the second epitaxial layer 202 in the first active region 400, and to form a doped region 250 having the second conductivity type (e.g., P-type) on the doped region 248. After performing the ion implantation processes, an annealing process may be performed to activate the dopants in the doped regions 248 and 250. In some embodiments, the annealing process includes laser annealing, rapid thermal annealing (RTA), another suitable annealing process, or a combination thereof.

Next, as shown in FIG. 21, after the doped regions 248 and 250 are formed, an etching process may be performed to remove the dielectric layer 242 and the dielectric layer 244R in the trench 232 and the trench 240. In some embodiments, the etching process may include a wet etching process. Different wet chemistries may be used to remove dielectric layer 242 such as silicon oxide and dielectric layer 244R such as silicon nitride.

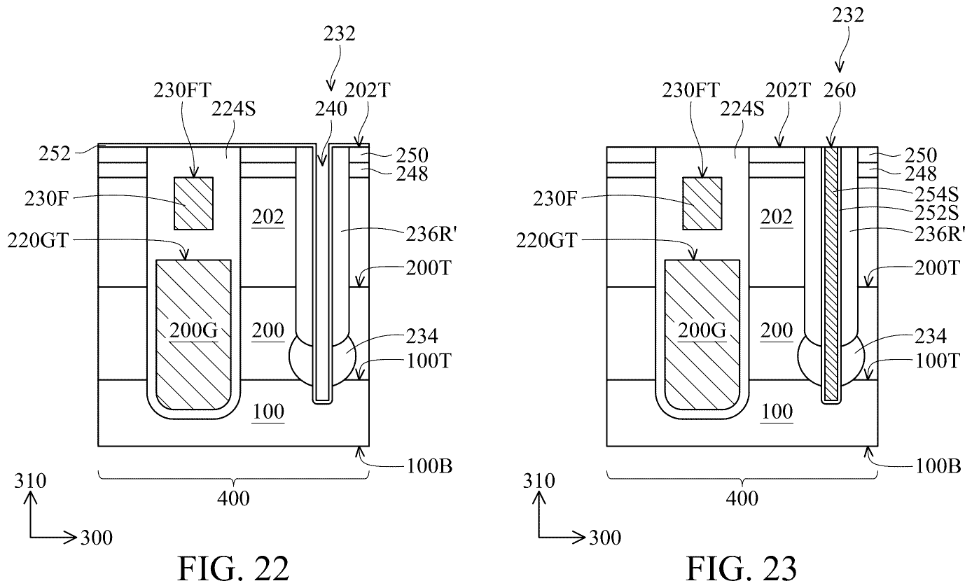

Next, as shown in FIG. 22, a deposition process and a subsequent annealing process may be performed to conformally form a metal silicide (not shown) on the opposite sidewalls and bottom surfaces of the doped region 250 and the trench 240, and to conformally form a first contact barrier layer 252 on the top surface 202T of the second epitaxial layer 202 and in the trenches 232, 240. The metal silicide (not shown) and the first contact barrier layer 252 do not completely fill the trench 232 and the trench 240.

Next, as shown in FIG. 23, a deposition process and a subsequent etching process may be performed to form a first contact barrier layer 252S and a first contact conductive layer 254S in the trench 232 and the trench 240. The first contact conductive layer 254S fills up the remaining space in the trench 232 and the trench 240. After performing the afore-mentioned processes, a first contact feature 260 (including a metal silicide (not shown), a first contact barrier layer 252S and a first contact conductive layer 254S) is formed in the trench 232 and the trench 240. The first contact feature 260 extends through the second epitaxial layer 202 and the first epitaxial layer 200, and into a portion of the silicon carbide substrate 100 in the direction 310.

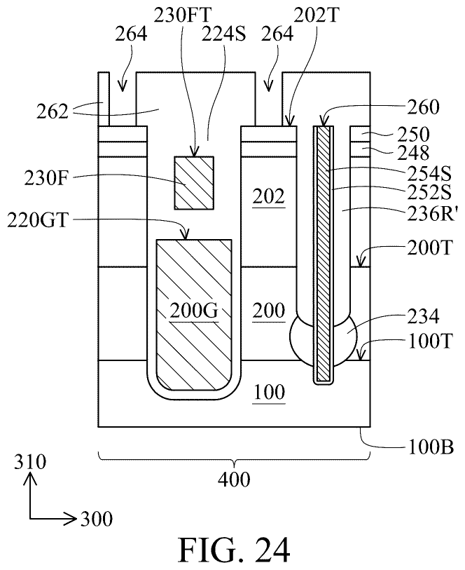

Next, as shown in FIG. 24, a deposition process and a subsequent patterning process may be performed to form an interlayer dielectric layer 262 on the second epitaxial layer 202. The interlayer dielectric layer 262 covers the electrode 230F, the gate structure 222 and the first contact feature 260. Furthermore, the interlayer dielectric layer 262 has an opening 264 exposing a portion of the doped region 250. When the interlayer dielectric layer 262, the gate dielectric layer 216, the shielding dielectric layer 224S and the dielectric layer 236R′ all include the same material (e.g., silicon oxide), the interfaces between the above elements are not obvious.

Next, as shown in FIG. 1, processes similar to those shown in FIG. 22 may be performed to form a second contact feature 270 including a metal silicide (not shown), a second contact barrier layer 266D and a second contact conductive layer 268D on the doped region 250 in the opening 264 of the interlayer dielectric layer 262. The metal silicide (not shown) of the second contact feature 270 covers the doped region 250 in the opening 264 (FIG. 24). The second contact barrier layer 266D is conformally formed on opposite side-walls and the bottom surface of the opening 264. The second contact conductive layer 268D fills up the remaining space in the opening 264. Next, processes similar to those shown in FIG. 22 may be performed to form a third contact feature 280 electrically connected to the silicon carbide substrate 100 on the bottom surface 100B of the silicon carbide substrate 100.

Next, as shown in FIG. 1, a deposition process and a subsequent patterning process may be performed to form a metal layer 290 electrically connected to the second contact feature 270 on the interlayer dielectric layer 262 in the first active region 400. After performing the aforementioned processes, the first type semiconductor component HVD of the semiconductor device 500 is formed.

In some embodiments, during the formation of the first type semiconductor component HVD, the second type semiconductor component LVD as shown in FIG. 1 may be formed in the second active region 410. After performing the aforementioned processes, a semiconductor device 500 is formed.

Embodiments of the disclosure provide a semiconductor device and a method for forming the same. Compared to conventional trench insulated gate bipolar transistors, the first type semiconductor component (e.g., the first type semiconductor component HVD) of the semiconductor device is an emitter-down (or gate-down) trench insulated gate bipolar transistor (emitter-down trench IGBT), in which the positions of the emitter and base are inverted. For example, the first type semiconductor component uses the bottom N-type heavily doped silicon carbide substrate (e.g., the silicon carbide substrate 100) as the emitter (source) region, and arrange a P-type first epitaxial layer (e.g., the first epitaxial layer 200) (the channel region) between the N-type lightly doped second epitaxial layer 202 (the drift region) and the N-type heavily doped silicon carbide substrate (the emitter region) along the vertical direction (e.g., the direction 310). The P-type heavily doped region (e.g., the doped region 250) (the collector (drain) region) of the first type semiconductor component is disposed at the top surface of the uppermost second epitaxial layer (e.g., the second epitaxial layer 202) (the drift region). The gate of the first type semiconductor component (e.g., the gate structure 222) passes through the P-type first epitaxial layer (the channel region) and extends to a portion of the N-type lightly doped second epitaxial layer (the drift region) and a portion of the N-type heavily doped silicon carbide substrate (the emitter region). Furthermore, the emitter contact feature (e.g., the first contact feature 260) of the first type semi-conductor component is electrically connected to both the N-type heavily doped silicon carbide substrate (the emitter region) and the P-type first epitaxial layer (the channel region), and extends upward from the bottom silicon carbide substrate (the emitter region) along a vertical direction (e.g., the direction 310) to the top second epitaxial layer. Therefore, the emitter (the N-type heavily doped silicon carbide substrate) and the collector (the P-type heavily doped region) of the first type semiconductor component are both close to the top surface of the second epitaxial layer and can be manufactured using a semiconductor front-end process. No complicated backside processing such as backside grinding or laser annealing is required. In addition, the emitter contact feature (e.g., the first contact feature 260), the collector contact feature (e.g., the second contact feature 270), and the contact feature (not shown) coupling to the gate (e.g., the gate structure 222) of the first type semiconductor component may all be arranged on the top surface of the second epitaxial layer (the drift region) and electrically connected to an external circuit (not shown) through the upper internal connection structure (not shown).

In some embodiments, the shielding electrode (e.g., the electrode 230F) of the first type semiconductor component is disposed between the gate (e.g., the gate structure 222) and the P-type heavily doped region (the collector region) (e.g., the doped region 250), which may reduce the gate-to-collector charge (Qgc) of the first type semiconductor component, increase the switching speed, and reduce dynamic loss.

In the semiconductor device, the first type semiconductor component such as the high voltage vertical device and the second type semiconductor component such as the low voltage lateral device (such as the second type semiconductor component LVD) may be manufactured by using the semiconductor front-end process. In addition, each of the contact features and metal layers that electrically connects the first type semiconductor component and the second type semiconductor element may be disposed on the top surface of the second epitaxial layer (the same side of the semiconductor device), and electrically connected to an external circuit (not shown) through an internal connection structure (not shown) above the top surface of the second epitaxial layer. Furthermore, the trench isolation dielectric layer (e.g., the dielectric layer 236R′) and the first contact feature (e.g., the first contact feature 260) formed therein may be used as electrical isolation features (in physical isolation and junction isolation) between the first type semiconductor component and the second type semiconductor element. Therefore, the same set of semiconductor processes may be used to integrate the first type semiconductor component and the second type semiconductor element with different channel directions on the same silicon carbide substrate. There is no need to use an external substrate such as a printed circuit board to electrically connect the first type semiconductor component and the second type semiconductor element respectively manufactured by different sets of semiconductor manufacturing processes.

Embodiments of the disclosure provide semiconductor devices and methods for forming the same. The semiconductor device includes a silicon carbide substrate, a first epitaxial layer, a second epitaxial layer, a first gate structure, and a first contact feature. The silicon carbide substrate has a first active region and a first conductivity type. The first epitaxial layer is disposed on the top surface of the silicon carbide substrate. The first epitaxial layer has a second conductivity type. The second epitaxial layer is disposed on the top surface of the first epitaxial layer. The second epitaxial layer has the first conductivity type. The first gate structure is disposed in the silicon carbide substrate in the first active region. The first gate structure extends from the silicon carbide substrate and passes through the first epitaxial layer in a first direction. The first contact feature extends from the top surface of the second epitaxial layer of the first active region and passes through the first epitaxial layer into the silicon carbide substrate in the first direction. The first contact feature and the first gate structure are separated from each other in the second direction. The first contact feature is electrically connected to the silicon carbide substrate and the first epitaxial layer.

In some embodiments, the semiconductor device also includes a first electrode and a shielding dielectric layer. The first electrode is disposed in the second epitaxial layer of the first active region. The first electrode is located directly above the first gate structure and extends in the first direction. The first electrode is electrically connected to the first contact feature. The shielding dielectric layer surrounds the first electrode.

In some embodiments, the semiconductor device also includes a first dielectric layer and a first doped region. The first dielectric layer extends from the second epitaxial layer in the first active region into a portion of the first epitaxial layer in a first direction. The first dielectric layer surrounds the first contact feature, and the bottom of the first contact feature protrudes from the bottom surface of the first dielectric layer. The first doped region is in the first epitaxial layer below the bottom surface of the first dielectric layer and sur-rounds the bottom of the first contact feature. The first doped region has the second conductivity type.

In some embodiments, the first doped region is in contact with the silicon carbide substrate.

In some embodiments, the shielding dielectric layer and the first dielectric layer have the same thickness.

In some embodiments, the semiconductor device also includes a second doped region, a third doped region, and a second contact feature. The second doped region is located in the second epitaxial layer in the first active region. The second doped region has the first conductivity type. The third doped region is located on the second doped region and close to the top surface of the second epitaxial layer. The third doped region has the second conductivity type. The second contact feature is disposed on the second epitaxial layer of the first active region and is electrically connected to the third doped region.

In some embodiments, the semiconductor device also includes a third contact feature. The third contact feature is disposed on a bottom surface of the silicon carbide substrate. The third contact feature is electrically connected to the silicon carbide substrate.

In some embodiments, the first gate structure in the first active region, the silicon carbide substrate and the third doped region form a trench insulated gate bipolar transistor. The first gate structure forms the gate of the trench insulated gate bipolar transistor. The silicon carbide substrate forms the emitter of the trench insulated gate bipolar transistor. In addition, the third doped region forms the collector of the trench insulated gate bipolar transistor.

In some embodiments, the silicon carbide substrate has a second active region. The semiconductor device also includes a first well region, a second gate structure, a fourth doped region, a fifth doped region, and a sixth doped region. The first well region is located in the second epitaxial layer in the second active region and is separated from the first gate structure by a first contact feature. The second gate structure is disposed on the first well region. The fourth doped region and the fifth doped region are located on the first well region and on two opposite sides of the second gate structure. The fourth doped region and the fifth doped region have the same conductivity type, which is the opposite of that of the first well region. The sixth doped region is located on the first well region and is adjacent to the fourth doped region. The sixth doped region and the first well region have the same conductivity type.

In some embodiments, the second gate structure extends in the second direction, and the second direction is different from the first direction.

In some embodiments, the first well region has the second conductivity type. The fourth doped region and the fifth doped region have the first conductivity type.

In some embodiments, the first well region has the first conductivity type. The fourth doped region and the fifth doped region have the second conductivity type.

In some embodiments, the first well region, the second gate structure, the fourth doped region, the fifth doped region and the sixth doped region in the second active region form a metal-oxide-semiconductor field-effect transistor. The second gate structure forms the gate of the metal-oxide-semiconductor field-effect transistor. The fourth doped region and the fifth doped region form the source and the drain of the metal-oxide-semiconductor field-effect transistor. The first well region and the fifth doped region form the bulk of the metal-oxide-semiconductor field-effect transistor.

In some embodiments, the trench insulated gate bipolar transistor has a first channel region, the metal-oxide-semiconductor field-effect transistor has a second channel region. The first channel region and the second channel region have different channel length directions.

Embodiments of the disclosure provide a method for forming a semiconductor device. The method includes providing a silicon carbide substrate having a first active region and a first conductivity type. The method also includes growing a first epitaxial layer on a top surface of the silicon carbide substrate. The first epitaxial layer has a second conductivity type. The method also includes growing a second epitaxial layer on a top surface of the first epitaxial layer. The second epitaxial layer has a first conductivity type. The method also includes forming a first trench in the second epitaxial layer, the first epitaxial layer and a portion of the silicon carbide substrate in the first active region in a first direction. The method also includes forming a first gate electrode in the first trench. The method also includes forming a second trench in the second epitaxial layer and a portion of the first epitaxial layer in the first active region in the first direction. The first trench and the second trench are spaced apart from each other in a second direction. The method also includes forming a first contact feature in the second trench. The first contact feature extends through the first epitaxial layer and into the silicon carbide substrate in the first direction.

In some embodiments, the first gate electrode fills a lower portion of the first trench, and a top surface of the first gate electrode is located above the top surface of the first epitaxial layer.

In some embodiments, the method for forming a semiconductor device also includes forming a mask pattern on the top surface of the second epitaxial layer. The method also includes removing the first epitaxial layer, the second epitaxial layer and a portion of the silicon carbide substrate not covered by the mask pattern to form a first trench. The method also includes removing the mask pattern after forming the first trench. The method also includes conformally forming a first gate dielectric layer in the first trench before forming the first gate electrode.

In some embodiments, the method for forming a semiconductor device also includes conformally forming a shielding dielectric layer in the first trench after forming the first gate electrode. The method also includes forming a first electrode on the shielding dielectric layer in the first trench. The method also includes forming a second trench after forming the first electrode.

In some embodiments, the method for forming a semiconductor device also includes forming a first doped region in the first epitaxial layer exposed from a bottom surface of the second trench before forming the first contact feature. The first doped region has the second conductivity type. The method also includes conformally forming a first dielectric layer in the second trench. The method also includes removing the first dielectric layer on the bottom surface of the second trench and the first epitaxial layer and the silicon carbide substrate thereunder to form a third trench. The third trench passes through the first doped region into the silicon carbide substrate.

In some embodiments, the method for forming a semiconductor device also includes forming a second dielectric layer in the first epitaxial layer and the silicon carbide substrate exposed from the third trench. The method also includes forming a third dielectric layer in the second trench and the third trench. The second dielectric layer and the third dielectric layer are formed of different materials. The method also includes forming a second doped region in the second epitaxial layer in the first active region. The second doped region has the first conductivity type. The method also includes forming a third doped region on the second doped region. The third doped region has the second conductivity type. The method also includes removing the second dielectric layer and the third dielectric layer after forming the second doped region and the third doped region.

In some embodiments, the method for forming a semiconductor device also includes forming a second contact feature on the third doped region after forming the first contact feature.

In some embodiments, the method for forming a semiconductor device also includes forming a third contact feature on a bottom surface of the silicon carbide substrate. The third contact feature is electrically connected to the silicon carbide substrate.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a silicon carbide substrate having a first active region and a first conductivity type;
a first epitaxial layer disposed on a top surface of the silicon carbide substrate, wherein the first epitaxial layer has a second conductivity type;
a second epitaxial layer disposed on a top surface of the first epitaxial layer, wherein the second epitaxial layer has the first conductivity type;
a first gate structure disposed in the first active region of the silicon carbide substrate, wherein the first gate structure extends from the silicon carbide substrate through the first epitaxial layer in a first direction; and
a first contact feature extending from a top surface of the second epitaxial layer of the first active region, through the first epitaxial layer and to the silicon carbide substrate in the first direction, wherein the first contact feature and the first gate structure are separated from each other in a second direction, and the first contact feature is electrically connected to the silicon carbide substrate and the first epitaxial layer.

2. The semiconductor device as claimed in claim 1, further comprising:
a first electrode disposed in the second epitaxial layer in the first active region, wherein the first electrode is located directly above the first gate structure and extends in the first direction, and the first electrode is electrically connected to the first contact feature; and
a shielding dielectric layer surrounding the first electrode.

3. The semiconductor device as claimed in claim 2, further comprising:
a first dielectric layer extending from the second epitaxial layer in the first active region to a portion of the first epitaxial layer in the first direction, wherein the first dielectric layer surrounds the first contact feature, and a bottom of the first contact feature protrudes from a bottom surface of the first dielectric layer; and
a first doped region located in the first epitaxial layer below the bottom surface of the first dielectric layer and surrounding the bottom of the first contact feature, wherein the first doped region has the second conductivity type.

4. The semiconductor device as claimed in claim 3, wherein the first doped region is in contact with the silicon carbide substrate.

5. The semiconductor device as claimed in claim 3, wherein the shielding dielectric layer and the first dielectric layer have the same thickness.

6. The semiconductor device as claimed in claim 3, further comprising:
a second doped region located in the second epitaxial layer in the first active region, wherein the second doped region has the first conductivity type;
a third doped region located on the second doped region and close to the top surface of the second epitaxial layer, wherein the third doped region has the second conductivity type; and
a second contact feature disposed on the second epitaxial layer in the first active region and electrically connected to the third doped region.

7. The semiconductor device as claimed in claim 1, further comprising:
a third contact feature disposed on a bottom surface of the silicon carbide substrate, wherein the third contact feature is electrically connected to the silicon carbide substrate.

8. The semiconductor device as claimed in claim 6, wherein the first gate structure in the first active region, the silicon carbide substrate and the third doped region form a trench insulated gate bipolar transistor, the first gate structure forms a gate of the trench insulated gate bipolar transistor, the silicon carbide substrate forms an emitter of the trench insulated gate bipolar transistor, and the third doped region forms a collector of the trench insulated gate bipolar transistor.

9. The semiconductor device as claimed in claim 8, wherein the silicon carbide substrate has a second active region, and the semiconductor device further comprises:
a first well region located in the second epitaxial layer in the second active region and separated from the first gate structure by the first contact feature;
a second gate structure disposed on the first well region;
a fourth doped region and a fifth doped region located on the first well region and on opposite sides of the second gate structure, wherein the fourth doped region and the fifth doped region have the same conductivity type that is opposite of the conductivity type of the first well region; and
a sixth doped region located on the first well region, wherein the sixth doped region and the first well region have the same conductivity type.

10. The semiconductor device as claimed in claim 9, wherein the second gate structure extends in the second direction, and the second direction is different from the first direction.

11. The semiconductor device as claimed in claim 9, wherein the first well region, the second gate structure, the fourth doped region, the fifth doped region and the sixth doped region in the second active region form a metal-oxide-semiconductor field-effect transistor, the second gate structure forms a gate of the metal-oxide-semiconductor field-effect transistor, the fourth doped region and the fifth doped region form a source and a drain of the metal-oxide-semiconductor field-effect transistor, and the first well region and the fifth doped region form a bulk of the metal-oxide-semiconductor field-effect transistor.

12. The semiconductor device as claimed in claim 11, wherein the trench insulated gate bipolar transistor has a first channel region, the metal-oxide-semiconductor field-effect transistor has a second channel region, and the first channel region and the second channel region have different channel length directions.

13. A method for forming a semiconductor device, comprising:
providing a silicon carbide substrate, wherein the silicon carbide substrate has a first active region and a first conductivity type;
growing a first epitaxial layer on a top surface of the silicon carbide substrate, wherein the first epitaxial layer has a second conductivity type;
growing a second epitaxial layer on a top surface of the first epitaxial layer, wherein the second epitaxial layer has the first conductivity type;
forming a first trench in the second epitaxial layer, the first epitaxial layer and a portion of the silicon carbide substrate in the first active region in a first direction;
forming a first gate electrode in the first trench;
forming a second trench in the second epitaxial layer and a portion of the first epitaxial layer in the first active region in the first direction, wherein the first trench and the second trench are spaced apart from each other in a second direction; and
forming a first contact feature in the second trench, wherein the first contact feature extends through the first epitaxial layer and into the silicon carbide substrate in the first direction.

14. The method for forming a semiconductor device as claimed in claim 13, wherein the first gate electrode fills a lower portion of the first trench, and a top surface of the first gate electrode is located above the top surface of the first epitaxial layer.

15. The method for forming a semiconductor device as claimed in claim 13, further comprising:
forming a mask pattern on a top surface of the second epitaxial layer;
removing the first epitaxial layer, the second epitaxial layer and a portion of the silicon carbide substrate not covered by the mask pattern to form the first trench;
removing the mask pattern after forming the first trench; and
conformally forming a first gate dielectric layer in the first trench before forming the first gate electrode.

16. The method for forming a semiconductor device as claimed in claim 15, further comprising:
conformally forming a shielding dielectric layer in the first trench after forming the first gate electrode; and
forming a first electrode on the shielding dielectric layer in the first trench; and
forming the second trench after forming the first electrode.

17. The method for forming a semiconductor device as claimed in claim 16, further comprising:
forming a first doped region in the first epitaxial layer exposed from a bottom surface of the second trench before forming the first contact feature, wherein the first doped region has the second conductivity type;
conformally forming a first dielectric layer in the second trench; and
removing the first dielectric layer on the bottom surface of the second trench and the first epitaxial layer and the silicon carbide substrate thereunder to form a third trench, wherein the third trench passes through the first doped region into the silicon carbide substrate.

18. The method for forming a semiconductor device as claimed in claim 17, further comprising:
forming a second dielectric layer in the first epitaxial layer and the silicon carbide substrate exposed from the third trench;
forming a third dielectric layer in the second trench and the third trench, wherein the second dielectric layer and the third dielectric layer are formed of different materials;
forming a second doped region in the second epitaxial layer in the first active region, wherein the second doped region has the first conductivity type;
forming a third doped region on the second doped region, wherein the third doped region has the second conductivity type; and
removing the second dielectric layer and the third dielectric layer after forming the second doped region and the third doped region.

19. The method for forming a semiconductor device as claimed in claim 18, further comprising:
forming a second contact feature on the third doped region after forming the first contact feature.

20. The method for forming a semiconductor device as claimed in claim 18, further comprising:
forming a third contact feature on a bottom surface of the silicon carbide substrate, wherein the third contact feature is electrically connected to the silicon carbide substrate.
